(19) United States
(12) Patent Application Publication
(10) Pub. No.: US 2025/0131151 A1
(43) Pub. Date: Apr. 24, 2025

(54) MEASUREMENT METHOD FOR HIERARCHICAL STRUCTURE OF URBAN SUPERBLOCK

(71) Applicant: SOUTHEAST UNIVERSITY, Nanjing, Jiangsu (CN)

(72) Inventors: Yacheng SONG, Nanjing, Jiangsu (CN); Dongqing HAN, Nanjing, Jiangsu (CN)

(21) Appl. No.: 18/042,415

(22) PCT Filed: Aug. 19, 2022
(86) PCT No.: PCT/CN2022/113618

§ 371 Date: Feb. 21, 2023

(30) Foreign Application Priority Data
Oct. 27, 2021 (CN) 202111257532.X

(51) Int. Cl. G06F 30/20

(52) U.S. Cl. CPC G06F 30/20

(57) ABSTRACT

The present disclosure discloses a measurement method for a hierarchical structure of a superblock, which belongs to the technical field of urban design, and includes the following steps of: according to categories of urban block morphology studies, determining “geometry” and “configuration” as cognition perspectives, determining that measurement objects include “network” and “area”, establishing a hierarchy matrix formed by intersection of “perspective” and “object”, dividing morphological characteristic measurement of superblocks into four quadrants, providing an indicator system of block morphological hierarchical structures and a calculation method thereof, and performing visual comparison and analysis on superblocks. The present disclosure provides a scientific method for further exploring the internal mechanism and rule of the block morphology, provides a technical tool for the current situation evaluation of the urban built environment and the future practice optimization direction, and promotes the development of micro-level digital urban design methods.

### TECHNICAL FIELD

The present disclosure belongs to the technical field of urban design, and in particular relates to a measurement method for a hierarchical structure of a superblock.

### BACKGROUND

Introverted giant street blocks divided by taking urban traffic trunk roads (or large river courses, forests and city walls) as boundaries are regarded as superblocks. In terms of the study on the street network, Shelton B proposed the three-level structure of the street network (2012), and Peponis J studied the multi-scale hierarchical characteristics of the block micro-network using the directional distance analysis method in spatial syntax (2015). In the study on the area structure, British scholars Martin L and March L, for the first time, systematically used digital models to study urban density (1975). In 2005, Pont M B and Haupt P of Delft University in the Netherlands constructed a space matrix method, and established a visual correlation between four indicators, namely, floor area ratio (FSI), coverage (GSI), openness (OSI) and layers (L), and built morphology. In 2019, Moudon AV, an urban morphologist, proposed a conceptual framework that integrates four aspects including area, network, super grid and superblock. These measurement methods for the morphology of the superblocks only focus on a single element, the study on the hierarchical structure of the overall morphology lacks integrity and comprehensiveness, and no specific calculation method is given, resulting in that the designed block morphology cannot achieve the desired ideal state.

### SUMMARY

In view of the shortcomings of the existing technology, the purpose of the present disclosure is to provide a measurement method for a hierarchical structure of a superblock, which can give consideration to the road network and the development land, and can associate the two attributes of geometric scale and topological structure together, so that the morphological characteristics of the superblocks can be better recognized and understood, and the most ideal block morphology can be designed.

The purpose of the present disclosure can be realized through the following technical solutions:

A measurement method for a hierarchical structure of a superblock, wherein the measurement method includes the following steps:
S1: according to categories of urban block morphology studies, determining “geometry” and “configuration” as cognition perspectives, determining that measurement objects include “network” and “area”, and establishing a hierarchy matrix cross plot formed by intersection of “perspective” and “object”;
S2: determining positions of morphological characteristic measurement relationships of different aspects of the superblocks in each quadrant of the plot; and
S3: providing a quantitative method for each quadrant based on a hierarchy matrix to describe a hierarchical order of a pattern and perform accurate analysis and comparison on the hierarchical structure between the blocks.

Further, in step S1, the “perspective” is divided into two directions of “geometry” and “configuration”, and the “object” includes two aspects of “network” and “area”.

Further, in step S2, the block morphology measurement relationships corresponding to the quadrants are as follows:
an upper quadrant describes a topological connection relationship of a street in a network;
a right quadrant describes a geometric geometry such as width and length of a street;
a left quadrant describes a connection relationship between plots and streets and a connection relationship between plots; and
a lower quadrant describes the scale size and development intensity of a plot.

Further, in step S3, the analysis on the hierarchical structure between the blocks includes calculation of type grades of individual elements, calculation of quadrant indicators and obtaining of hierarchical results of the whole block in each quadrant.

The present disclosure has the following beneficial effects:

The present disclosure provides a universal quantitative tool for the identification of superblock structures through the hierarchy matrix. A regional block structure feature can be extracted through a large number of sample analysis, so as to derive the value of the ideal interval, thereby providing clear guidance for the design and reconstruction direction. Through the comparison between the current structure and the ideal interval, the reconstruction direction and degree of the block morphology can be clearly obtained, and it is helpful to accurately select the reconstruction strategy to make the design result reach the ideal state. At the same time, the present disclosure not only provides a scientific method for further exploring the internal mechanism and law of the superblock morphology, but also establishes a mathematical basis for opening up the two links of morphology cognition and morphology design, and promotes the development of micro-level digital urban design methods.

### BRIEF DESCRIPTION OF THE DRAWINGS

In order to more clearly describe the embodiments of the present disclosure or the technical solutions in the existing technology, the following will briefly introduce the drawings needed in the description of the embodiments or the existing technology. It is obvious that for those skilled in the art, other drawings may be obtained from these drawings without contributing any inventive labor.

FIG. 1 illustrates a hierarchy matrix cognition cross plot formed by intersection of “perspective” and “object”.

FIG. 2 illustrates a hierarchy diagram of an overall structure.

FIG. 3 illustrates hierarchy matrix diagrams of eight sample blocks.

FIG. 4 illustrates general situations of eight sample blocks.

### DETAILED DESCRIPTION

With reference to the drawings in the embodiments of the present disclosure, the technical solutions in the embodiments of the present disclosure will be described clearly and completely. Obviously, the described embodiments are only part of the embodiments of the present disclosure, not all of them. Based on the embodiments of the present disclosure, all other embodiments obtained by those skilled in the art without contributing any inventive labor still fall within the scope of the present disclosure.

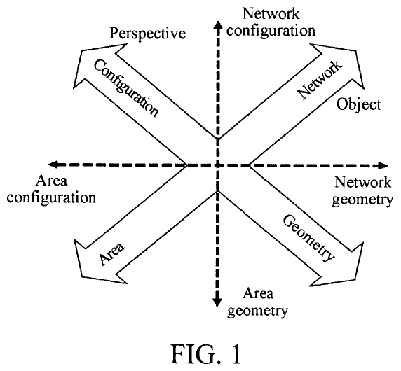

The morphological characteristics of superblocks can be described as, in regional units enclosed by urban trunk roads (large rivers, forests, city walls, and the like), morphological elements with different scale sizes interweave in a complex topological network through some logical relationship. In order to scientifically understand the implicit logical relationship, the present disclosure provides a set of targeted cognitive methods—hierarchy matrix. In the field of urban morphology, the three basic morphological elements of streets, plots and buildings can be described by pattern language. “Network” refers to the street system, and “area” refers to the plane area formed by the plots occupied by the buildings. Geometry and configuration are two perspectives to observe the same element. The former focuses on the geometric scale attribute of elements, while the latter focuses on the abstract topological relationship between elements. On this basis, a measurement method for a hierarchical structure of a superblock is designed. The measurement method includes the following steps:
S1: according to categories of urban block morphology studies, as illustrated in FIG. 1, “geometry” and “configuration” are determined as cognition perspectives, it is determined that measurement objects include “network” and “area”, and a hierarchy matrix cross plot formed by intersection of “perspective” and “object” is established. The “perspective” is divided into two directions of “geometry” and “configuration”. The “object” includes two aspects of “network” and “area”. For several categories of urban block morphology studies, corresponding positions can be found in this hierarchy matrix.
S2: positions of morphological characteristic measurement relationships of the superblocks in each quadrant of the plot are determined. For example, describing the connection relationship of a certain street in a network belongs to the scope of the upper quadrant. When describing the geometric geometry of the street, such as its width and length, it is shifted to the right quadrant. If you focus on the connection relationship between plots and streets and the connection relationship between plots, the perspective will shift to the left quadrant. The scale size and development intensity of the plot belong to the scope of the lower quadrant. The four quadrants correspond to each other, which can be used for more comprehensively and systematically understanding the hierarchical structure of the superblock.
S3: a quantitative method is provided for each quadrant based on a hierarchy matrix to describe a hierarchical order of a pattern and perform accurate analysis and comparison on the hierarchical structure between the blocks. First, it is needed to perform the calculation of type grade values of individual elements. In terms of network configuration, the boundary roads that define the blocks are determined as the benchmark elements, the depth value is set as 0, and the connectivity is determined as infinite. On this basis, depth and connectivity values are assigned to the internal streets. The depth value of the street directly connected with the boundary street is 1, and the depth value of the street directly connected with the street with the depth value of 1 is 2, and so on. The connectivity value describes the number of other streets within the block connected by the street. If a street is connected with 3 other streets, the connectivity value of the street is 3. The lower the depth value and the higher the connectivity value, the higher the grade of the street (the grade of the boundary road is always the highest, and the grade of the internal street decreases sequentially). Conversely, the lower the grade. In terms of network geometry, the grade of the street is identified by the width and length of the street. The greater the width and length, the higher the grade of the street. Conversely, the lower the grade of the street. In terms of area configuration, the grade of the plot is equal to the network configuration grade value of the street where its main entrance/exit is located. For a plot that needs to pass through other plots, its grade is equal to the configuration grade of the connected plot plus 1. In terms of area geometry, the grade of the area is determined based on the floor area ratio and building coverage ratio. The higher the floor area ratio and the greater the building coverage ratio, the higher the grade. Conversely, the lower the grade. The basic data for calculating type grades of individual elements in each quadrant is shown in Table 1.

TABLE 1
Basic data for calculating type grade values
of individual elements in each quadrant

| Quadrant | Basic data |
|---|---|
| Network configuration | Depth and connectivity |
| Network geometry | Length and width |
| Area configuration | Assign a value according to a network |
| | configuration value of a street where |
| | an entrance/exit of a plot is located |
| Area geometry | Floor area ratio and building coverage ratio |

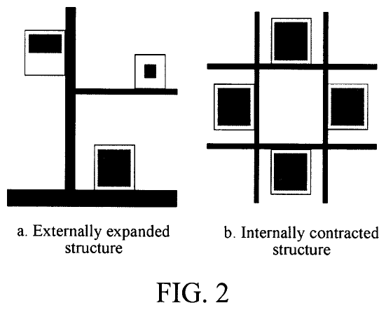

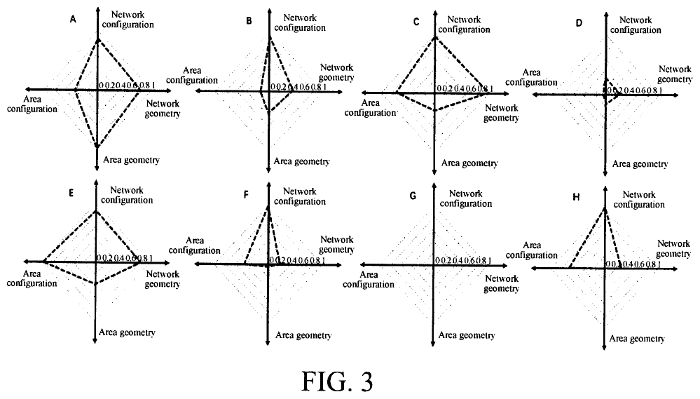

The types of individual elements are ordered according to the determination criteria of grades, and quantity values contained in each type are determined. As illustrated in FIG. 2, samples a and b are taken as examples. Sample a has 3 grade types in each of four quadrants, and each type contains 1 element. Sample b has only 1 grade type in each of four quadrants, but each type contains 4 elements. In a case that the basic data are complex, the similarity between elements can be found through cluster analysis to facilitate scientific classification. Cluster analysis is widely used for distinguishing morphological types. The greater the similarity (or homogeneity) between types, the greater the difference between types, and the better (or more obvious) the clustering scheme. The number of types is determined according to the number of individual elements of the sample blocks, basic data interval and clustering quality.

In addition, a variance operation is performed on elements in each quadrant according to type grade value results of individual elements to obtain an absolute hierarchy value in each quadrant. A calculation formula is as follow:

$$α = {\sum }_{i = 1}^{n} {( {x}_{i} - M )}^{2} / n$$

where α represents an absolute hierarchy value;
xi represents a value of an individual element (street or plot) with a serial number i;
M represents a mean of type grade values of the same type of individual elements in a block; and
n represents a total number of individuals with the same type grade in a block.

Absolute hierarchy value results of all blocks are sequentially normalized to obtain numerical values between 0 and 1, that is, relative hierarchy values of blocks in each quadrant. A calculation formula is as follow:

$$β = ( α - {α}_{min} ) / ( {α}_{max} - {α}_{min} )$$

where β represents a relative hierarchy value;
α represents an absolute hierarchy value of a quadrant;
αₘᵢₙ represents a minimum absolute hierarchy value in all elements; and
αₘₐₓ represents a maximum absolute hierarchy value in all elements.

The relative hierarchy value is used for describing the hierarchical characteristics of the composition elements within the block, and can be used for horizontal comparison between blocks. The more dispersed the distribution of individual element type grade values in a quadrant, the higher the relative hierarchy value, which means the higher the hierarchy of this quadrant. Conversely, the more concentrated the distribution of type grade values, the lower the relative hierarchy value, which means the lower the hierarchy of this quadrant. As illustrated in FIG. 2, the block with the structure in FIG. a show a higher hierarchy in each of four quadrants than that with the structure in FIG. b, so the former has more layers in the hierarchy matrix than the latter.

Data of four quadrants are normalized through absolute hierarchy value calculation according to the type grade value results of the individual elements in the block to obtain relative hierarchy values usable for comparison and analysis.

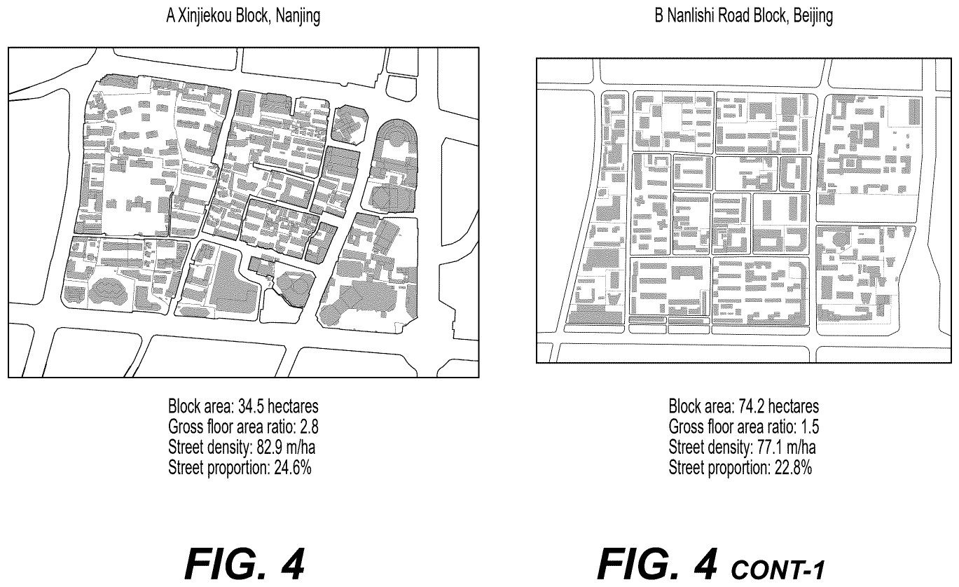

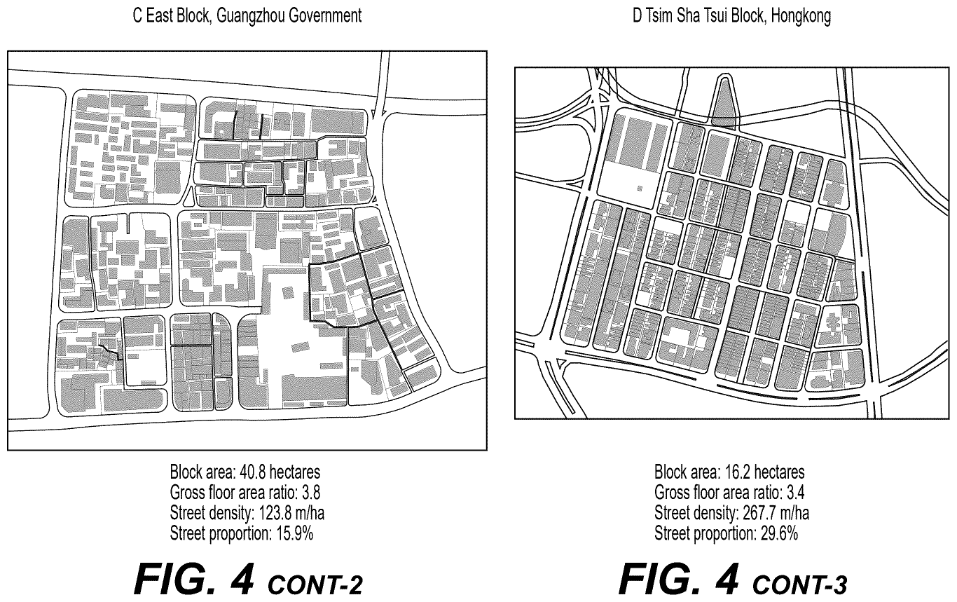

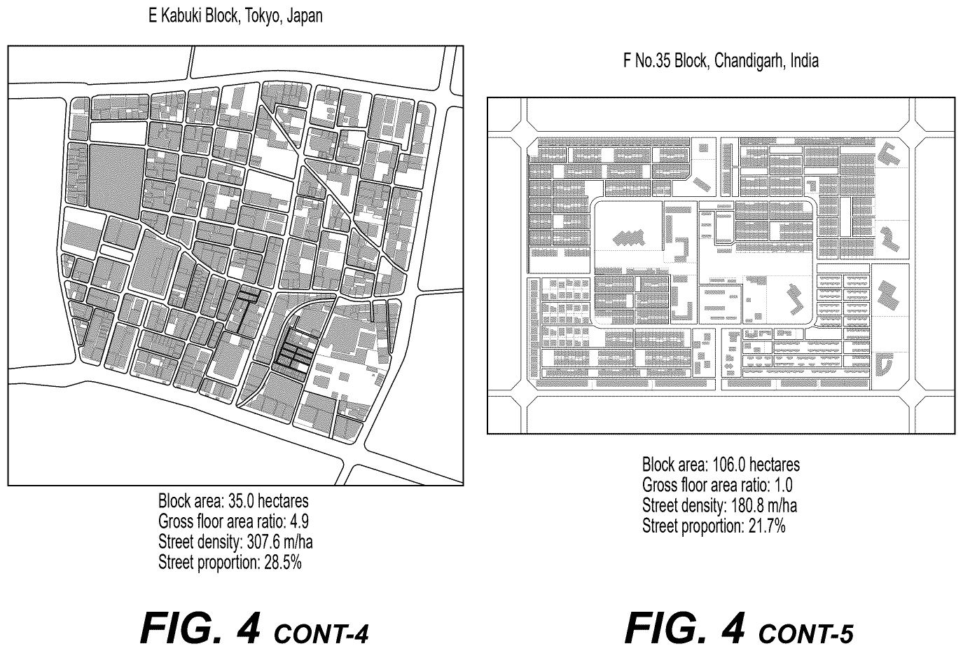

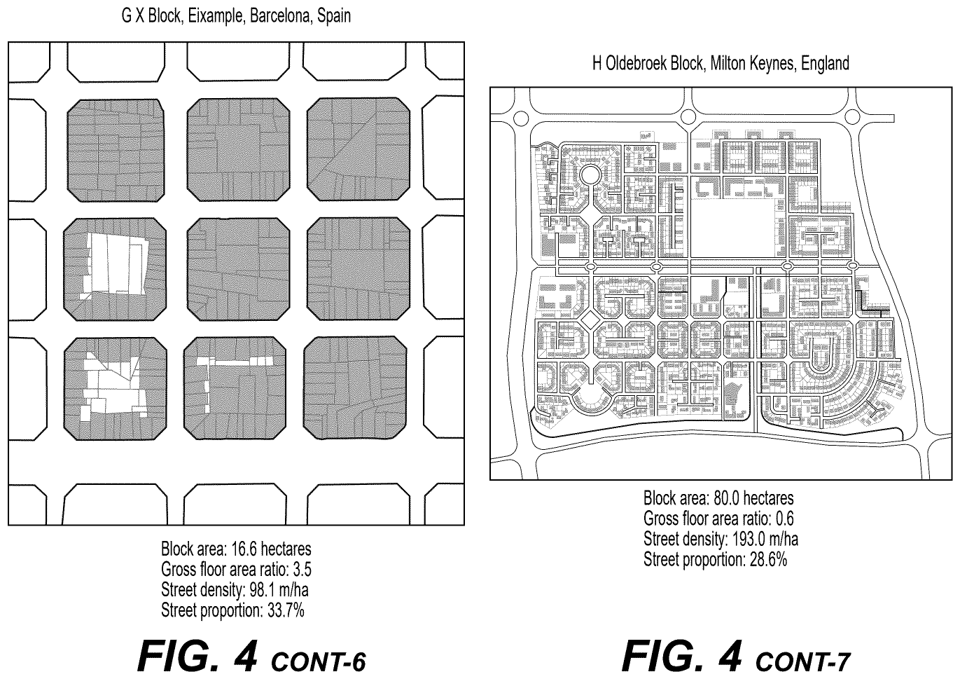

In a specific embodiment, eight blocks at home and abroad were selected for comparison, as shown in FIG. 4. National samples were the old city centers of Beijing, Nanjing, Guangzhou and Hong Kong, with large differences in social background and climate environment. The selected block E in Tokyo of Japan and block G in Barcelona of Spain are located in the centers of the old cities, both of which have experienced local planning adjustment. Samples F and H were constructed under the control of top-down planning, fully reflecting the concept of the designer.

Hierarchical measurement was performed on eight representative blocks at home and abroad respectively from four quadrants. Through cluster analysis, 16 network configuration grades, 10 network geometry grades, 12 area geometry grades, and 16 area configuration grades were obtained. Relative hierarchy values were presented in a radar map, as illustrated in FIG. 4 and Table 2. Samples A, C and E show obvious hierarchical characteristics, but they all have an obvious weak item, A is weak in area configuration, while C and E are weak in area geometry. Samples B, F and H show an obvious “eccentric” structure, all of which are very strong in network configuration and weak in the other three items. The structures of samples F and H are very similar, showing moderate hierarchy in network geometry and area configuration, while the hierarchy in area geometry is extremely low. Sample B shows moderate hierarchy in network geometry and area geometry, and the hierarchy in area configuration is obviously low. The overall hierarchy of samples D and G is obviously lower than that of other samples. The difference is that the former is slightly higher than the latter in terms of various indicators.

Except for grid blocks D and G, all other blocks show a strong hierarchy in network configuration, and the differentiation of street types is a significant basic feature of blocks. The highly hierarchical samples A, C and E are all located in the old city environment, covering a number of historical textures from the Ming and Qing dynasties to the present, and the self-updating from the bottom up has a significant positive correlation effect on the construction of the hierarchy. Although sample B is adjacent to the old city, due to the relatively overall reconstruction, the history span of the existing texture is small, so the hierarchy is not prominent. Samples F and H are blocks formed with clear design intent. Although designers have tried to shape diversified places through network configuration, the scale of streets and buildings is too homogeneous, which inhibits the hierarchy of geometric geometry. Samples D and G are in homogenized grids. Although they have undergone purposeful differentiated reconstruction in the later period, it is still difficult to change the structural background of weak hierarchy.

TABLE 2
Hierarchical structures of eight sample blocks

| | Network | | | | | | | |
|---|---|---|---|---|---|---|---|---|
| | configuration | | Network geometry | | Area geometry | | Area configuration | |
| | Absolute | Relative | Absolute | Relative | Absolute | Relative | Absolute | Relative |
| | hierarchy | hierarchy | hierarchy | hierarchy | hierarchy | hierarchy | hierarchy | hierarchy |
| | value | value | value | value | value | value | value | value |
| A | 1.63 | 0.84 | 4.95 | 0.78 | 3.72 | 1 | 5.30 | 0.42 |
| B | 1.75 | 0.90 | 2.82 | 0.44 | 1.56 | 0.38 | 2.12 | 0.15 |
| C | 1.80 | 0.93 | 6.38 | 1 | 1.30 | 0.31 | 8.92 | 0.72 |
| D | 0.56 | 0.29 | 1.65 | 0.26 | 0.73 | 0.15 | 0.88 | 0.05 |
| E | 1.66 | 0.85 | 5.20 | 0.82 | 1.50 | 0.37 | 12.28 | 1 |
| F | 1.87 | 0.96 | 1.33 | 0.21 | 0.28 | 0.02 | 5.62 | 0.44 |
| G | 0 | 0 | 0 | 0 | 0.38 | 0.05 | 0.29 | 0 |
| H | 1.95 | 1 | 1.98 | 0.31 | 0.21 | 0 | 7.61 | 0.61 |

In the description, the description with reference to the terms “one embodiment”, “example”, “specific example” and the like indicates that the specific features, structures, materials or features described in combination with this embodiment or example are included in at least one embodiment or example of the present disclosure. In the description, the schematic expressions of the above terms do not necessarily refer to the same embodiments or examples. Moreover, the specific features, structures, materials or characteristics described may be combined in an appropriate manner in any one or more embodiments or examples.

The basic principle, main features and advantages of the present disclosure are shown and described above. Those skilled in the art should understand that the present disclosure is not limited by the above embodiments, and what are described in the above embodiments and the description are only intended to describe the principle of the present disclosure. Without departing from the spirit and scope of the present disclosure, the present disclosure may also have various changes and improvements, which, however, still fall within the scope of protection of the present disclosure.

What is claimed is:

1. A measurement method for a hierarchical structure of a superblock, wherein the measurement method comprises the following steps:
S1: according to categories of urban block morphology studies, determining “geometry” and “configuration” as cognition perspectives, determining that measurement objects comprise “network” and “area”, and establishing a hierarchy matrix cross plot formed by intersection of “perspective” and “object”;
S2: determining positions of morphological characteristic measurement relationships of different aspects of the superblocks in each quadrant of the plot; and
S3: providing a quantitative method for each quadrant based on a hierarchy matrix to describe a hierarchical order of a pattern and perform accurate analysis and comparison on the hierarchical structure between the blocks.

2. The measurement method for a hierarchical structure of a superblock according to claim 1, wherein in step S1, the “perspective” is divided into two directions of “geometry” and “configuration”, and the “object” comprises two aspects of “network” and “area”.

3. The measurement method for a hierarchical structure of a superblock according to claim 1, wherein in step S2, the block morphology measurement relationships corresponding to the quadrants are as follows:
an upper quadrant describes a topological connection relationship of a street in a network;
a right quadrant describes a geometric geometry such as width and length of a street;
a left quadrant describes a connection relationship between plots and streets and a connection relationship between plots; and
a lower quadrant describes the scale size and development intensity of a plot.

4. The measurement method for a hierarchical structure of a superblock according to claim 1, wherein in step S3, the analysis on the hierarchical structure between the blocks comprises calculation of type grades of individual elements, calculation of quadrant indicators and obtaining of hierarchical results of the whole block in each quadrant.

5. The measurement method for a hierarchical structure of a superblock according to claim 4, wherein the calculation of the type grades of the individual elements comprises:
1) determining basic data of network configuration, network geometry, area configuration and area geometry;
2) performing cluster analysis on individual elements according to the obtained basic data of individual elements to find the similarity between elements and perform classification; and
3) ordering types obtained through clustering according to determination of a grade relationship to obtain a grade value of each type;
the calculation of the quadrant indicators comprises:
performing a variance operation on elements in each quadrant according to type grade value results of individual elements to obtain an absolute hierarchy value in each quadrant, and a calculation formula being as follow:
$$α = {\sum }_{i = 1}^{n} {( {x}_{i} - M )}^{2} / n$$
where α represents an absolute hierarchy value;
xi represents a value of an individual element (street or plot) with a serial number i;
M represents a mean of type grade values of the same type of individual elements in a block; and
n represents a total number of individuals with the same type grade in a block;
sequentially normalizing absolute hierarchy value results of all blocks to obtain numerical values between 0 and 1, that is, relative hierarchy values of blocks in each quadrant, and a calculation formula being as follow:
$$β = ( α - {α}_{min} ) / ( {α}_{max} - {α}_{min} )$$
where β represents a relative hierarchy value;
α represents an absolute hierarchy value of a quadrant;
αₘᵢₙ represents a minimum absolute hierarchy value in all elements; and
αₘₐₓ represents a maximum absolute hierarchy value in all elements; and
the obtaining of the hierarchical results of the whole block in each quadrant comprises:
normalizing data of four quadrants through absolute hierarchy value calculation according to the type grade value results of the individual elements in the block to obtain relative hierarchy values usable for comparison and analysis.
